(19) United States
(12) Patent Application Publication
(10) Pub. No.: US 2018/0106834 A1
(43) Pub. Date: Apr. 19, 2018

(54) TEST FIXTURE AND TEST SYSTEM APPLICABLE TO ELECTRONIC DEVICE HAVING UNIVERSAL SERIAL BUS TYPE-C RECEPTACLE, AND METHOD FOR PERFORMING TESTING ON ELECTRONIC DEVICE WITH AID OF TEST FIXTURE

(71) Applicant: JMicron Technology Corp., Hsin-Chu (TW)

(72) Inventors: Chi-Hsin Liu, Hsinchu City (TW); Tzu-Sen Hsiao, Miaoli County (TW)

(21) Appl. No.: 15/585,178

(22) Filed: May 3, 2017

Related U.S. Application Data
(60) Provisional application No. 62/408,036, filed on Oct. 13, 2016.

(30) Foreign Application Priority Data
Nov. 22, 2016 (TW) 105138177

(51) Int. Cl. G01R 1/04; G05B 11/01; H01R 24/60; H01R 13/70; G01R 1/20

(52) U.S. Cl. CPC G01R 1/0416; G05B 11/01; H01R 2107/00; H01R 13/70; G01R 1/206; H01R 24/60

(57) ABSTRACT

A test fixture includes a plug adaptable to a Universal Serial Bus (USB) Type-C receptacle, a switching circuit, and a control circuit. The plug can be utilized for coupling an electronic device under test. The switching circuit can be utilized for performing switching operations to enable first and second sets of communication paths within the test fixture in turn. The first and the second sets of communication paths are coupled to a first set of communication terminals of the plug and a second set of communication terminals of the plug, respectively. The control circuit can be utilized for controlling the switching operations, to allow a processing circuit to perform first and second sets testing operations on the electronic device through the first and the second sets of communication paths, respectively. A test system and a method for performing testing with aid of the test fixture are also provided.

### CROSS REFERENCE TO RELATED APPLICATIONS

This application claims the benefit of U.S. Provisional Application No. 62/408,036, filed on Oct. 13, 2016 and included herein by reference.

### BACKGROUND OF THE INVENTION

### 1. Field of the Invention

The present invention relates to a test of an electronic device, and more particularly, to a test fixture, a test system, and a method for performing testing on an electronic device with aid of the above test fixture, wherein the electronic device has a Universal Serial Bus (USB) Type-C receptacle.

### 2. Description of the Prior Art

During a test process of an electronic device has a Universal Serial Bus (USB) Type-C receptacle, an operation user has to plug a plug of a cable into the USB Type-C receptacle to test certain terminals of the USB Type-C receptacle. After finishing a first test, the operation user has to unplug the plug and turn the plug around (such as turn a top surface of the plug to be a bottom surface of the plug), and then plug the plug into the USB Type-C receptacle again to test certain terminals of the USB Type-C receptacle. After finishing a second test, the operation user has to unplug the plug. In addition, for a next device under test (DUT) (such as another electronic device of the same type), the operation user can repeat the above operation motions. Based on the test scheme of related techniques, certain problems will happen. For example, since the operation user has to turn the plug around, the operation user may forget which side is the current test side, or another side misses the test. Or, plugging and unplugging the plug a lot of times may damage the plug contact to make mistake in the test. Thus, an innovative scheme and related method is required to reduce possibility of the mistakes happening (such as miss test or test mistakes) and increase test efficiency.

### SUMMARY OF THE INVENTION

It is therefore one of the objectives of the present invention to provide a test fixture, a test system, and a method for performing testing on an electronic device with aid of the above test fixture can reduce operation motions of the operation user during the entire test process, and reduce possibility of damage the plug, and reduce test time of each device under test (DUT), and increase test efficiency, so as to solve the above problem.

In accordance with at least an embodiment of the present invention, a test fixture is disclosed, wherein the test fixture is applicable to an electronic device having a Universal Serial Bus (USB) Type-C receptacle. The test fixture comprises a plug adaptable to a Universal Serial Bus (USB) Type-C receptacle, a switching circuit, and a control circuit. The plug can be utilized for coupling an electronic device under test. The switching circuit can be utilized for performing switching operations to enable first and second sets of communication paths within the test fixture in turn. The first and the second sets of communication paths are coupled to a first set of communication terminals of the plug and a second set of communication terminals of the plug, respectively. The control circuit can be utilized for controlling the switching operations, to allow a processing circuit to perform first and second sets testing operations on the electronic device through the first and the second sets of communication paths, respectively. The plug adaptable to a USB Type-C receptacle can be utilized for coupling the electronic device under test, wherein the plug has a plurality of terminals positioned respectively on a first side and a second side of the plug. The switching circuit can be utilized for performing switching operations to enable a first set of communication paths and a second set of communication paths within the test fixture in turn, wherein the first set of communication paths is coupled to a first set of communication terminals of the plug and a second set of communication paths is coupled to a second set of communication terminals of the plug. The control circuit can be utilized for controlling the switching operations to allow a processing circuit in a test system to perform a first set of testing operations on the electronic device through the first set of communication paths, and perform a second set testing operations on the electronic device through the second set of communication paths, wherein the test system comprises the test fixture.

In accordance with at least an embodiment of the present invention, a method for performing testing on the electronic device with aid of the above test fixture is also provided, wherein the method is applicable to the processing circuit, and the method comprises: using the control circuit to control at least a switching operation of the switching operations of the switching circuit, to enable the first set of communication paths within the test fixture; performing the first set of testing operations on the electronic device via the first set of communication paths; using the control circuit to control at least a switching operation of the switching operations of the switching circuit, to enable the second set of communication paths within the test fixture; and performing the second set of testing operations on the electronic device via the second set of communication paths.

In accordance with at least an embodiment of the present invention, a test system applicable to an electronic device having a Universal Serial Bus (USB) Type-C receptacle is also provided. The test system comprising: a processing circuit and a test fixture. The processing circuit can be utilized for control operations of the test system. The test fixture comprises a plug adaptable to a Universal Serial Bus (USB) Type-C receptacle, a switching circuit, and a control circuit. The plug can be utilized for coupling an electronic device under test. The switching circuit can be utilized for performing switching operations to enable first and second sets of communication paths within the test fixture in turn. The first and the second sets of communication paths are coupled to a first set of communication terminals of the plug and a second set of communication terminals of the plug, respectively. The control circuit can be utilized for controlling the switching operations, to allow a processing circuit to perform first and second sets testing operations on the electronic device through the first and the second sets of communication paths, respectively. The plug adaptable to a USB Type-C receptacle can be utilized for coupling the electronic device under test, wherein the plug has a plurality of terminals positioned respectively on a first side and a second side of the plug. The switching circuit can be utilized for performing switching operations to enable a first set of communication paths and a second set of communication paths within the test fixture in turn, wherein the first set of communication paths is coupled to a first set of communication terminals of the plug and a second set of communication paths is coupled to a second set of communication terminals of the plug. The control circuit can be utilized for controlling the switching operations to allow the processing circuit to perform a first set of testing operations on the electronic device through the first set of communication paths, and perform a second set testing operations on the electronic device through the second set of communication paths.

The test fixture, the test system, and the method for performing testing on an electronic device with aid of the above test fixture disclosed by the present invention can reduce operation motions of the operation user during the entire test process, and reduce possibility of damage the plug, and reduce test time of each device under test (DUT), and increase test efficiency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a simplified block diagram of a test system and an electronic device in accordance with an embodiment of the present invention

FIG. 2 shows details of the related terminals in FIG. 1 in accordance with an embodiment.

FIG. 3 is a flowchart showing a method for performing testing on the electronic device with aid of the test fixture.

FIG. 4 shows details of the related terminals in FIG. 1 in accordance with another embodiment.

### DETAILED DESCRIPTION

The present invention discloses a test fixture, a test system, and a method for performing testing on an electronic device with aid of the above test fixture, wherein the electronic device has a Universal Serial Bus (USB) Type-C receptacle, and is capable of performing a communication operation in accordance with the USB Type-C spec. The test fixture and the test system are applicable to the electronic device, to reduce operation motions of operation user during the entire test process, and reduce possibility of damage the plug, and reduce test time of each device under test (DUT), and increase test efficiency.

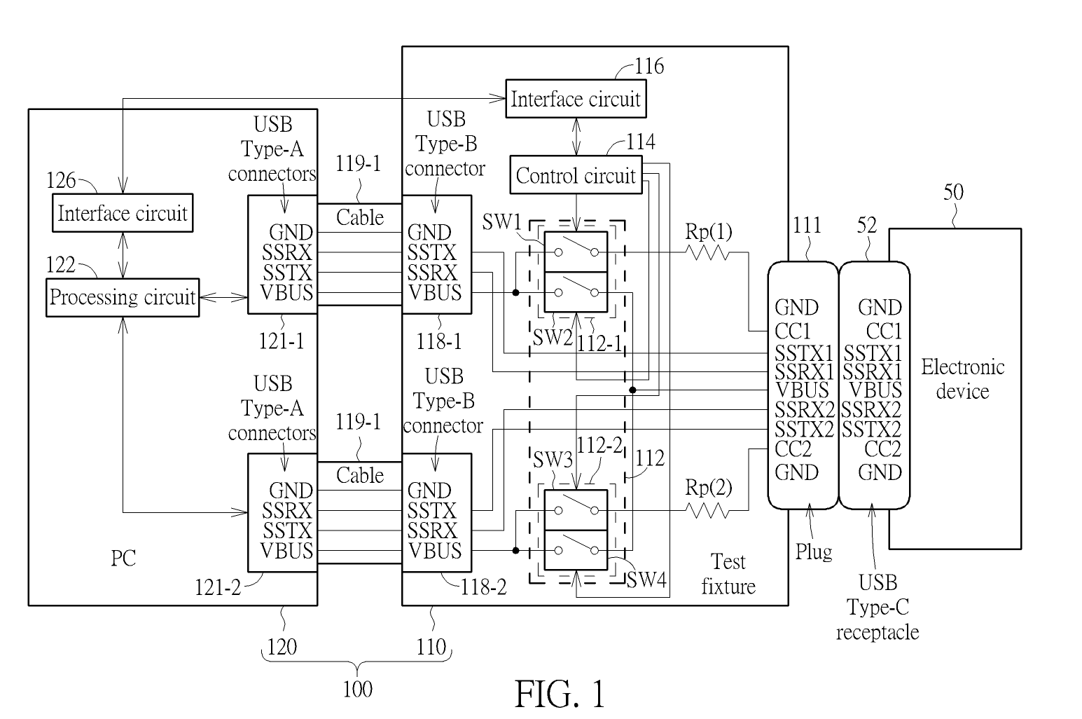

Please refer to FIG. 1. FIG. 1 shows a simplified block diagram of a test system 100 and an electronic device 50 in accordance with an embodiment of the present invention, wherein Type-C receptacle 52, the test system 100 and the electronic device 50 can be examples of the test fixture, the test system and the electronic device mentioned above, respectively. Since the test system 100 can test the electronic device 50 via with aid of Type-C receptacle 52, the electronic device 50 can be viewed as a DUT. The electronic device 50 has a USB Type-C receptacle 52, and the USB Type-C receptacle 52 comprises a plurality of terminals such as {GND, CC1, SSTX1, SSRX1, VBUS, SSRX2, SSTX2, CC2, GND}. In USB Type-C receptacle 52, any one of the terminals SSTX1, SSRX1, SSRX2, and SSTX2 represents two differential communication terminals for transmitting a differential pair, and the terminal VBUS represents a set of power terminals, and the terminal GND represents a set of ground terminals, and the terminal CC1 and CC2 both are Configuration Channel (CC) terminals. For example, the electronic device 50 can be an external hard disk (HD), and external HD box, or any one of various types of electronic devices.

As shown in FIG. 1, the test fixture 110 comprises a plug 111 adaptable to the USB Type-C receptacle 52. The plug 111 can be utilized for coupling the electronic device 50, and the plug 111 comprises a plurality of terminals. When the plug 111 is plugged into the USB Type-C receptacle 52, the terminals {GND, CC1, SSTX1, SSRX1, VBUS, SSRX2, SSTX2, CC2, GND} of the plurality of terminals can be coupled to the terminals {GND, CC1, SSTX1, SSRX1, VBUS, SSRX2, SSTX2, CC2, GND} of the USB Type-C receptacle 52, respectively. In the plurality of terminals, the terminals SSTX1, SSRX1, SSRX2, and SSTX2 represents two differential communication terminals for transmitting a differential pair, and the terminal VBUS represents a set of power terminals, and the terminal GND represents a set of ground terminals, and the terminal CC1 and CC2 both are CC terminals, wherein the set of ground terminals are coupled to each other, and the set of ground terminals are coupled to each other, and coupled to the ground of the test fixture 110. For example, the plug 111 can be a USB Type-C plug. Since the USB Type-C receptacle 52 and the plug 111 are flat shaped, the plug 111 has two side, such as a first side (e.g. a side where the terminal CC1 of plug 111 is on) and a second ide (e.g. a side where the terminal CC2 of plug 111 is on), wherein the plurality of terminals are positioned on the two sides, respectively. In addition, the test fixture 110 further comprises a switching circuit 112, a control circuit 114, an interface circuit 116, resistors Rp(1) and Rp(2), and a plurality of USB connector such as the Type-B connector 118-1 and 118-2. For example, the switching circuit 112 comprises: a first set of switches 112-1 and a second set of switches 112-2, wherein the first set of switches 112-1 comprises switches SW1 and SW2, and the second set of switches 112-2 comprises switches SW3 and SW4. In this embodiment the switches SW1, SW2, SW3, and SW4 can be Metal Oxide Semiconductor Field Effect Transistor (MOSFET), and the control circuit 114 can be a controller such as a micro controller. The interface circuit 116 can be any interface matches the present communication specs, such as USB, RS-232, or I2C. In addition, the test system 100 can further comprise a personal computer (PC) 120, wherein the PC 120 comprises the USB Type-A connectors 121-1 and 121-2, a processing circuit 122, and an interface circuit 126. The processing circuit 122 can control operations of the test system 100. For example, the processing circuit 122 can comprise at least a processor and related control circuit of the PC 120, and the at least a processor mentioned above can execute the program code to control operations of the test system 100. The interface circuit 126 can be any interface fits the present communication specs, such as USB, RS-232, or I2C. For example, the interface circuit 116 and the interface circuit 126 can match the same communication spec.

In accordance with the embodiment, the switching circuit 112 can be utilized for performing switching operations to enable a first set of communication paths and a second set of communication paths within the test fixture 110 in turn, wherein the first set of communication paths is coupled to a first set of communication terminals {SSTX1, SSRX1} and a second set of communication paths is coupled to a second set of communication terminals {SSTX2, SSRX2}. For example, the first set of communication paths is coupled between the first set of communication terminals {SSTX1, SSRX1} and the terminals {SSTX, SSRX} of the USB Type-B connector 118-1, and the second set of communication paths is coupled between the second set of communication terminals {SSTX2, SSRX2} and the terminals {SSTX, SSRX} of the USB Type-B connector 118-2. The USB Type-B connectors 118-1 and 118-2 and couple the test fixture 110 to the PC 120 via the cables 119-1 and 119-2, respectively. As shown in FIG. 1, the terminals {GND, SSTX, SSRX, VBUS} of the USB Type-B connector 118-1 can be respectively coupled to the terminals {GND, SSTX, SSRX, VBUS} of the USB Type-A connector 121-1 via the cable 119-1, and the terminals {GND, SSTX, SSRX, VBUS} of the USB Type-B connector 118-2 can be respectively coupled to the terminals {GND, SSTX, SSRX, VBUS} of the USB Type-A connector 121-2 via the cable 119-2. In addition, the control circuit 114 can be utilized for controlling the switching operations of the switching circuit 112 to allow the processing circuit 122 to perform a first set of testing operations on the electronic device 50 through the first set of communication paths (which is coupled to the cable 119-1 in this embodiment), and perform a second set testing operations on the electronic device 50 through the second set of communication paths (which is coupled to the cable 119-2 in this embodiment). For example, the control circuit 114 can be coupled to the PC 120 via at least an interface (such as the interface circuit 116 and 126) to allow the processing circuit 122 to use the control circuit 114 to control the switching operations of the switching circuit 112.

As shown in FIG. 1, the resistor Rp(1) is coupled between the switch SW1 and the CC terminal CC1 of the plug 111, and the second resistor Rp(2) is coupled between the switch SW3 and the CC terminal CC2 of the plug 111, and the set of power terminals VBUS of the plug 111 are respectively coupled to the switches SW2 and SW4. The first set of switches 112-1 are coupled to the power terminal VBUS of the USB Type-B connector 118-1, and the second set of switches 112-2 are coupled to the power terminal VBUS of the USB Type-B connector 118-2. The control circuit 114 can respectively control the control terminals of the switches SW1, SW2, SW3, and SW4, such as the Gate of the MOSFETs. Under the control of the control circuit 114, the first set of switches 112-1 can selectively providing power to at least a terminal of the plurality of terminals positioned on the first side, such as the CC terminal CC1 of the plug 111 and the two power terminals VBUS on the same side. For example, when the control circuit 114 turns on the first set of switches 112-1, the first set of communication paths are enabled. In addition, under the control of the control circuit 114, the second set of switches 112-2 can selectively providing power to at least a terminal of the plurality of terminals positioned on the second side, such as the CC terminal CC2 of the plug 111 and the two power terminals VBUS on the same side. For example, when the control circuit 114 turns on the first set of switches 112-2, the second set of communication paths are enabled. In addition, under the control of the control circuit 114, the first set of switches 112-1 and the second set of switches 112-2 will not be turned on at the same time.

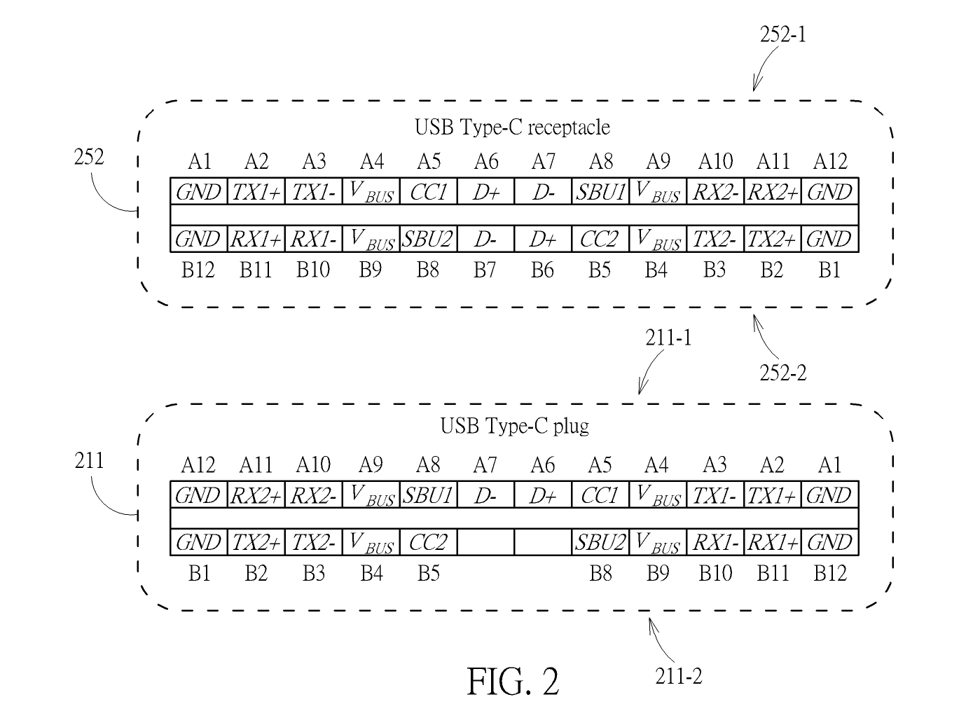

FIG. 2 shows details of the related terminals in FIG. 1, wherein the USB Type-C plug 211 can be an example of the plug 111, and the USB Type-C receptacle 252 can be an example of the USB TYPE-C receptacle 52. The USB Type-C receptacle 252 can have pins {A1, A2, A3, A4, A5, A6, A7, A8, A9, A10, A11, A12} and {B1, B2, B3, B4, B5, B6, B7, B8, B9, B10, B11, B12}, respectively positioned on a first side 252-1 and a second side 252-2 of the USB Type-C receptacle 252. For better understanding, the symbol in italics can represent the corresponding signal names in the USB Type-C Specification. For example, the pins {A1, A2, A3, A4, A5, A6, A7, A8, A9, A10, A11, A12} can be respectively assigned to signals {GND, TX1+, TX1−, V_{BUS}, CC1, D+, D−, SBU1, V_{BUS}, RX2−, RX2+, GND}, and the pins {B1, B2, B3, B4, B5, B6, B7, B8, B9, B10, B11, B12} can be respectively assigned to signals {GND, TX2+, TX2−, V_{BUS}, CC2, D+, D−, SBU2, V_{BUS}, RX1−, RX1+, GND}. In accordance with the embodiment, the terminals of the can be pins of the USB Type-C receptacle 252. For example, the terminals SSTX1, SSRX1, SSRX2, and SSTX2 can be respectively implemented as pins {A2, A3}, {B11, B10}, {A11, A10}, and {B2, B3}, and the set of power terminals represented by the terminal VBUS can be respectively implemented as pins {A4, A9, B4, B9}, the set of ground terminals represented by the terminal GND can be respectively implemented as pins {A1, A12, B1, B12}, and the terminals CC1 and CC2 can be respectively implemented as pins A5 and B5.

In addition, the USB Type-C plug 211 has corresponding pins {A1, A2, A3, A4, A5, A6, A7, A8, A9, A10, A11, A12} and {B1, B2, B3, B4, B5, B8, B9, B10, B11, B12}, respectively positioned on a first side 211-1 and a second side 211-2 of the USB Type-C plug 211, wherein there is no pins B6 and B7 in the USB Type-C plug 211 in this embodiment. In accordance with the embodiment, the plurality of terminals of the plug 111 can be implemented as pins of the USB Type-C plug 211. For example, in the plurality of terminals of the plug 111, the terminals SSTX1, SSRX1, SSRX2, and SSTX2 terminals can be respectively implemented as pins {A2, A3}, {B11, B10}, {A11, A10} and {B2, B3}, and the set of power terminals represented by the terminal VBUS terminal can be respectively implemented as pins {A4, A9, B4, B9}, and the set of ground terminals represented by the terminal GND can be respectively implemented as pins {A1, A12, B1, B12}, and the terminals CC1 and CC2 can be respectively implemented as pins A5 and B5.

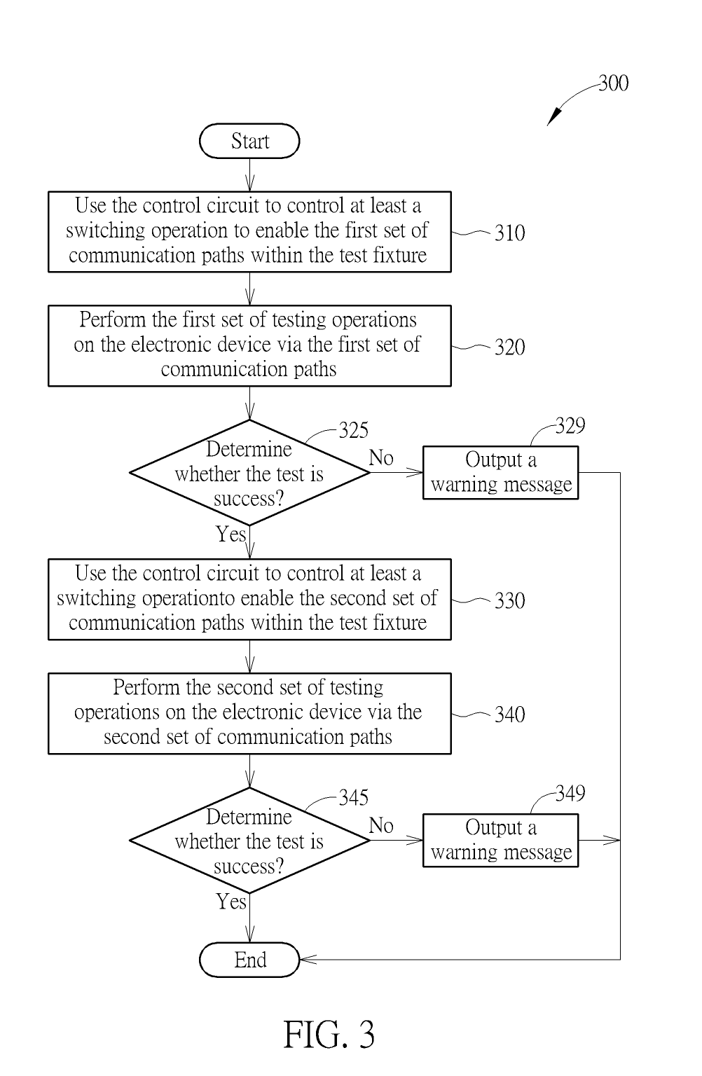

Please refer to FIG. 3. FIG. 3 is a flowchart showing a method 300 for performing testing on the electronic device 50 with aid of the test fixture 110, wherein the method 300 is applicable to the processing circuit 122, the PC 120, and the test system 100.

In the Step 310, the processing circuit 122 can use the control circuit 114 to control at least a switching operation of the switching operations, to enable the first set of communication paths within the test fixture 110. In this embodiment, the processing circuit 122 can use the control circuit 114 to control the switching circuit 112 to enable the first set of communication paths and disable the second set of communication paths. For example, the processing circuit 122 can use the control circuit 114 to control a first set of switches 112-1 of to perform a first set of switching operations of the switching operations to enable the first set of communication paths, wherein the control circuit 114 can turn on the switches SW1 and SW2, and turn off the switches SW3 and SW4, and the first set of switching operations can comprise turning on the switches SW1 and SW2. For example, before entering the Step 310, the processing circuit 122 can use the control circuit 114 to maintain the switching circuit 112 in a turn-off state.

In the Step 320, the processing circuit 122 can perform a first set of test operations (such as writing and reading operations) on the electronic device 50 via the first set of communication paths. For example, after the first set of test operations are finished, the processing circuit 122 can use the control circuit 114 to turn off the switching circuit 112.

In the Step 325, the processing circuit 122 can determine whether the test is success according to the test result of the first set of test operations. When the processing circuit 122 determines that the test is success, enters the Step 330; otherwise, enters the Step 329.

In the Step 329, the processing circuit 122 can output a warning message. For example, the warning message can indicate that the test is failed, and the operation user will know that the electronic device 50 needs to be repaired.

In the Step 330, the processing circuit 122 can use the control circuit 114 to control at least a switching operation of the switching operations, to enable the second set of communication paths within the test fixture 110. In this embodiment, the processing circuit 122 can use the control circuit 114 to control the switching circuit 112 to enable the second set of communication paths and disable the first set of communication paths. For example, the processing circuit 122 can use the control circuit 114 to control a second set of switches 112-2 of to perform a second set of switching operations of the switching operations to enable the second set of communication paths, wherein the control circuit 114 can turn off the switches SW1 and SW2, and turn on the switches SW3 and SW4, and the second set of switching operations can comprise turning on the switches SW3 and SW4. For example, after finishing the first set of test operations and before entering the Step 330, the processing circuit 122 can use the control circuit 114 to maintain the switching circuit 112 in a turn-off state.

In the Step 340, the processing circuit 122 can perform a second set of test operations (such as writing and reading operations) on the electronic device 50 via the second set of communication paths. For example, after the second set of test operations are finished, the processing circuit 122 can use the control circuit 114 to turn off the switching circuit 112.

In the Step 345, the processing circuit 122 can determine whether the test is success according to the test result of the second set of test operations. When the processing circuit 122 determines that the test is success, end the flow in FIG. 3; otherwise, enters the Step 349.

In the Step 349, the processing circuit 122 can output a warning message. For example, the warning message can indicate that the test is failed, and the operation user will know that the electronic device 50 needs to be repaired.

Based on the method 300, the present invention can reduce operation motions of the operation user during the entire test process, and reduce possibility of damage the plug, and reduce test time of each device under test (DUT), and increase test efficiency. Provided that substantially the same result is achieved, the steps of the process flowchart need not be in the exact order shown in FIG. 3 and need not be contiguous, that is, other steps can be intermediate.

In accordance with an embodiment, in the Step 345, when the processing circuit 122 determines that the test is success, the processing circuit 122 can output an indication message, and the flow in FIG. 3 is ended. For example, the indication message can indicate that the test is success, and then the operation user will perform the same test on the next DUT (such as another electronic device of the same type).

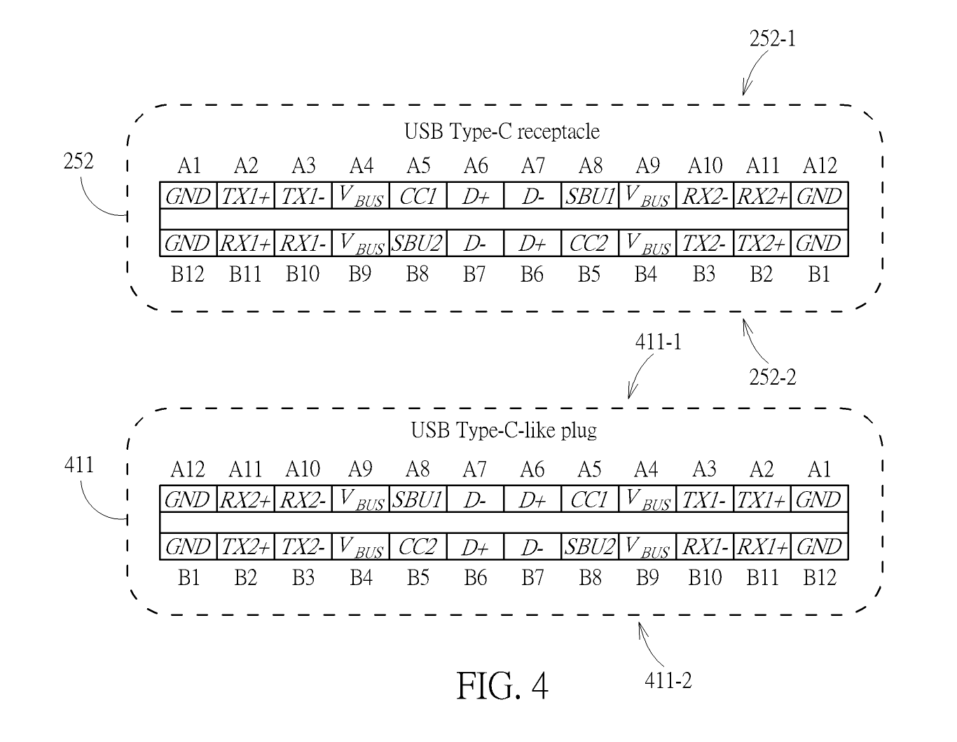

FIG. 4 shows details of the related terminals in FIG. 1 in accordance with another embodiment, wherein the USB Type-C-like plug 411 can be an example of the plug 111. In comparison with the USB Type-C plug 211 in FIG. 2, the USB Type-C-like plug 411 has corresponding pins {A1, A2, A3, A4, A5, A6, A7, A8, A9, A10, A11, A12} and {B1, B2, B3, B4, B5, B6, B7, B8, B9, B10, B11, B12}, respectively positioned on a first side 411-1 and a second side 411-2 of the USB Type-C-like plug 411. In the USB Type-C-like plug 411, the pins A6 and B6 are coupled to each other, and the pins A7 and Blare coupled to each other, to allow the operation user to plug the USB Type-C-like plug 411 into the USB Type-C receptacle 52, regardless whether the first side 411-1 or the second side 411-2 faces upwards. Thus, no matter the first side 411-1 or the second side 411-2 faces upwards, the signals D+ and D− can be transmitted between the test fixture 110 and the electronic device 50. For example, at least a set of communication paths of the first set of communication paths and the second set of communication paths can comprise the communication paths corresponding to the signals D+ and D−. Thus, the processing circuit 122 can perform another set of test operations (such as writing and reading operations) on the electronic device 50 via the first set of communication paths or the second set of communication paths.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A test fixture applicable to an electronic device having a Universal Serial Bus (USB) Type-C receptacle, the test fixture comprising:
a plug adaptable to a USB Type-C receptacle, for coupling the electronic device under test, wherein the plug has a plurality of terminals positioned respectively on a first side and a second side of the plug;
a switching circuit, for performing switching operations to enable a first set of communication paths and a second set of communication paths within the test fixture in turn, wherein the first set of communication paths is coupled to a first set of communication terminals of the plug and a second set of communication paths is coupled to a second set of communication terminals of the plug; and
a control circuit, for controlling the switching operations to allow a processing circuit in a test system to perform a first set of testing operations on the electronic device through the first set of communication paths, and perform a second set testing operations on the electronic device through the second set of communication paths, wherein the test system comprises the test fixture.

2. The test fixture of claim 1, wherein the test system comprises a personal computer (PC), and the processing circuit comprises at least a processor of the PC, and the test fixture further comprises:
a first USB connector, for coupling the test fixture to the PC, wherein the first set of communication paths are coupled between the first set of communication terminals and terminals of the first USB connector; and
a second USB connector, for coupling the test fixture to the PC, wherein the second set of communication paths are coupled between the second set of communication terminals and terminals of the second USB connector.

3. The test fixture of claim 2, wherein the switching circuit comprises:
a first set of switches, coupled to a power terminal of the first USB connector, for selectively providing power to at least a terminal of the plurality of terminals positioned on the first side, wherein when the control circuit turn on the first set of switches, the first set of communication paths are enabled; and
a second set of switches, coupled to a power terminal of the second USB connector, for selectively providing power to at least a terminal of the plurality of terminals positioned on the second side, wherein when the control circuit turn on the second set of switches, the second set of communication paths are enabled;
wherein the first set of switches and the second set of switches are not turned on at the same time under control of the control circuit.

4. The test fixture of claim 3, wherein the at least a terminal positioned on the first side comprises a first power terminal and a first Configuration Channel (CC) terminal; the at least a terminal positioned on the second side comprises a second power terminal and a second CC terminal; and the test fixture further comprises:
a first resistor, coupled between a switch of the first set of switches and the first CC terminal; and
a second resistor, coupled between a switch of the second set of switches and the second CC terminal.

5. The test fixture of claim 3, wherein a switch of the first set of switches is coupled between the power terminal of the first USB connector and a set of power terminals of the plurality of terminals, and the set of power terminals are coupled to each other;
and a switch of the second set of switches is coupled between the power terminal of the second USB connector and a set of power terminals of the plurality of terminals.

6. The test fixture of claim 5, further comprising:
a first resistor, coupled between another switch of the first set of switches and a CC terminal positioned on the first side; and
a second resistor, coupled between another switch of the second set of switches and the a CC terminal positioned on the second side.

7. The test fixture of claim 2, wherein the control circuit is coupled to the PC via at least an interface, to allow the processing circuit use the control circuit to control the switching operations of the switching circuit.

8. A method for performing testing on the electronic device with aid of the test fixture of claim 7, wherein the method is applicable to the processing circuit, and the method comprises:
using the control circuit to control at least a switching operation of the switching operations of the switching circuit, to enable the first set of communication paths within the test fixture;
performing the first set of testing operations on the electronic device via the first set of communication paths;
using the control circuit to control at least a switching operation of the switching operations of the switching circuit, to enable the second set of communication paths within the test fixture; and
performing the second set of testing operations on the electronic device via the second set of communication paths.

9. The method of claim 8, wherein the step of using the control circuit to control the at least a switching operation of the switching operations of the switching circuit to enable the first set of communication paths within the test fixture further comprises:
using the control circuit to control a first set of switches of the switching circuit to perform a first set of switching operations to enable the first set of communication paths, wherein the first set of switches are coupled to a power terminal of the first USB connector, to selectively provide power to at least a terminal of the plurality of terminals positioned on the first side, wherein when the control circuit turn on the first set of switches, the first set of communication paths are enabled; and
the step of using the control circuit to control the at least a switching operation of the switching operations of the switching circuit to enable the second set of communication paths within the test fixture further comprises:
using the control circuit to control a second set of switches of the switching circuit to perform a second set of switching operations to enable the second set of communication paths, wherein the second set of switches are coupled to a power terminal of the first USB connector, to selectively provide power to at least a terminal of the plurality of terminals positioned on the second side, wherein when the control circuit turn on the second set of switches, the second set of communication paths are enabled.

10. The method of claim 8, wherein the step of using the control circuit to control the at least a switching operation of the switching operations of the switching circuit to enable the first set of communication paths within the test fixture further comprises:
using the control circuit to enable the first set of communication paths and disable the second set of communication paths; and
the step of using the control circuit to control the at least a switching operation of the switching operations of the switching circuit to enable the second set of communication paths within the test fixture further comprises:
using the control circuit to enable the second set of communication paths and disable the first set of communication paths.

11. A test system applicable to an electronic device having a Universal Serial Bus (USB) Type-C receptacle, the test system comprising:
a processing circuit, for control operations of the test system; and
a test fixture comprising:
a plug adaptable to a USB Type-C receptacle, for coupling the electronic device under test, wherein the plug has a plurality of terminals positioned respectively on a first side and a second side of the plug;
a switching circuit, for performing switching operations to enable a first set of communication paths and a second set of communication paths within the test fixture in turn, wherein the first set of communication paths is coupled to a first set of communication terminals of the plug and a second set of communication paths is coupled to a second set of communication terminals of the plug; and
a control circuit, for controlling the switching operations to allow the processing to perform a first set of testing operations on the electronic device through the first set of communication paths, and perform a second set testing operations on the electronic device through the second set of communication paths.

12. The test system of claim 11, wherein the test system comprises a personal computer (PC), and the processing circuit comprises at least a processor of the PC, and the test fixture further comprises:
a first USB connector, for coupling the test fixture to the PC, wherein the first set of communication paths are coupled between the first set of communication terminals and terminals of the first USB connector; and
a second USB connector, for coupling the test fixture to the PC, wherein the second set of communication paths are coupled between the second set of communication terminals and terminals of the second USB connector.

13. The test system of claim 12, wherein the switching circuit comprises:
a first set of switches, coupled to a power terminal of the first USB connector, for selectively providing power to at least a terminal of the plurality of terminals positioned on the first side, wherein when the control circuit turn on the first set of switches, the first set of communication paths are enabled; and
a second set of switches, coupled to a power terminal of the second USB connector, for selectively providing power to at least a terminal of the plurality of terminals positioned on the second side, wherein when the control circuit turn on the second set of switches, the second set of communication paths are enabled;
wherein the first set of switches and the second set of switches are not turned on at the same time under control of the control circuit.

14. The test system of claim 13, wherein the at least a terminal positioned on the first side comprises a first power terminal and a first Configuration Channel (CC) terminal; the at least a terminal positioned on the second side comprises a second power terminal and a second CC terminal; and the test fixture further comprises:
a first resistor, coupled between a switch of the first set of switches and the first CC terminal; and
a second resistor, coupled between a switch of the second set of switches and the second CC terminal.

15. The test system of claim 13, wherein a switch of the first set of switches is coupled between the power terminal of the first USB connector and a set of power terminals of the plurality of terminals, and the set of power terminals are coupled to each other;
and a switch of the second set of switches is coupled between the power terminal of the second USB connector and a set of power terminals of the plurality of terminals.

16. The test system of claim 15, wherein the test fixture further comprises:
a first resistor, coupled between another switch of the first set of switches and a CC terminal positioned on the first side; and
a second resistor, coupled between another switch of the second set of switches and the a CC terminal positioned on the second side.

17. The test system of claim 12, wherein the control circuit is coupled to the PC via at least an interface, to allow the processing circuit use the control circuit to control the switching operations of the switching circuit.
